(19) United States
(12) Patent Application Publication
(10) Pub. No.: US 2006/0000799 A1
(43) Pub. Date: Jan. 5, 2006

(54) Methods and apparatus for determining endpoint in a plasma processing system

(76) Inventors: Hyun-Ho Doh, Livermore, CA (US); Brian K. McMillin, Fremont, CA (US)

Correspondence Address: IPSG, P.C., P.O. BOX 700640, SAN JOSE, CA, 95170-0640, US

(21) Appl. No.: 10/882,474

(22) Filed: Jun. 30, 2004

(51) Int. Cl. B44C 1/22; H01L 21/302

(52) U.S. Cl. 216/59; 216/58; 216/67; 438/710; 156/345.24

(57) ABSTRACT

In a plasma processing system, a method of determining a process threshold is disclosed. The method includes exposing a substrate to a plasma process, including a process start portion, a substantially steady state portion, and process end portion. The method also includes collecting a first set of data during the substantially steady state portion; creating a first statistical model comprising at least a statistical model component selected from the group consisting of a variance component and a residual component; and collecting a second set of data. The method further includes creating a second statistical model comprising the statistical model component, wherein if the statistical model component of the first statistical model is substantially different than the statistical model component of the second statistical model, the process threshold has been substantially achieved.

### REFERENCE TO RELATED APPLICATIONS

This application incorporates by reference U.S. Ser. No. 10/696,628 (LAM2P431/P1169) filed on Oct. 28, 2003.

### BACKGROUND OF THE INVENTION

The present invention relates in general to substrate manufacturing technologies and in particular to methods and apparatus for determining endpoint in a plasma processing system.

In the processing of a substrate, e.g., a semiconductor substrate or a glass panel such as one used in flat panel display manufacturing, plasma is often employed. As part of the processing of a substrate for example, the substrate is divided into a plurality of dies, or rectangular areas, each of which will become an integrated circuit. The substrate is then processed in a series of steps in which materials are selectively removed (etching) and deposited (deposition) in order to form electrical components thereon.

In an exemplary plasma process, a substrate is coated with a thin film of hardened emulsion (i.e., such as a photoresist mask) prior to etching. Areas of the hardened emulsion are then selectively removed, causing components of the underlying layer to become exposed. The substrate is then placed in a plasma processing chamber on a substrate support structure comprising a mono-polar or bi-polar electrode, called a chuck or pedestal. Appropriate etchant source are then flowed into the chamber and struck to form a plasma to etch exposed areas of the substrate.

FIG. 1 depicts a plasma processing system 150 including a chamber 100 equipped with a pump 120 to maintain a low chamber pressure and exhaust the process gas effluent. Chamber 100 is grounded as is the upper electrode 104 that also acts as a showerhead type gas distribution system. RF power is supplied from power source 101 to an electrostatic chuck (chuck) 108 situated on a lower electrode assembly 106. RF power source may include a means for matching to the plasma impedance by frequency tuning or by tuning a variable impedance in matching network 145. RF electrical measurements are made using probe 140 with signal communicated to process module controller 116 by cable 141. Plasma 102 is generated by supplying RF power to chuck 108 in order to process substrate 109. In this example system, plasma 102 is confined between chuck 108 and electrode 104 by means of confinement rings 103, which may control a pressure within plasma 102. Confinement rings 103 can be moved to increase and decrease a spacing or gap between adjacent confinement rings, commonly by the use of cam ring. Gas distribution system 122 is commonly comprised of compressed gas cylinders containing plasma processing gases (e.g., C₄F₈, C₄F₆, CHF₃, CH₂F₃, CF₄, HBr, CH₃F, C₂F₄, N₂, O₂, Ar, Xe, He, H₂, NH₃, SF₆, BCl₃, Cl₂, WF₆, etc).

During operation, plasma induced electromagnetic radiation (optical emission) may be collected through window 110 and imaged onto spectrometer 114 by means of lens 111 and fiber optic 112. The optical detector within spectrometer 114 transmits the spectrally resolved emission signals to etch process controller 116 by means of signal cable 115.

The spectrometer 114 may be preferably a commercially available unit such as model S2000 manufactured by Ocean Optics, Inc. Typically, the compact spectrometer would disperse and collect the spectral signals over a wavelength range between about 200 nm and about 850 nm, by means of an internal grating and optics, and an onboard CCD array with about 2048 pixels. With such a system, the optical resolution is typically about 1 nm. Optical emission spectra are collected while processing substrates at a sampling rate of about 1 to about 10 Hz

Generally, some type of cooling system is coupled to the chuck in order to achieve thermal equilibrium once the plasma is ignited. The cooling system itself is usually comprised of a chiller that pumps a coolant through cavities in within the chuck, and helium gas pressurizes the small gap between the chuck and the substrate. In addition to removing the generated heat, the helium gas also allows the cooling system to rapidly control heat dissipation. That is, increasing helium pressure subsequently also increases the heat transfer rate. Most plasma processing systems are also controlled by sophisticated computers comprising operating software programs. In a typical operating environment, manufacturing process parameters (e.g., voltage, gas flow mix, gas flow rate, pressure, etc.) are generally configured for a particular plasma processing system and a specific recipe.

In a common substrate manufacturing method, known as dual damascene, dielectric layers are electrically connected by a conductive plug filling a via hole. Generally, an opening is formed in a dielectric layer, usually lined with a TaN or TiN barrier, and then subsequently filled with a conductive material (e.g., aluminum (Al), copper (Cu), etc.) that allows electrical contact between two sets of conductive patterns. This establishes electrical contact between two active regions on the substrate, such as a source/drain region. Excess conductive material on the surface of the dielectric layer is typically removed by chemical mechanical polishing (CMP). A blanket layer of silicon nitride is then deposited to cap the copper.

There are generally three commonly used approaches for manufacturing dual damascene substrates: via-first, trench-first, and dual hard mask. In one example of the via-first methodology, the substrate is first coated with photoresist and then the vias are lithographically patterned. Next, an anisotropic etch cuts through the surface cap material and etches down through the low-k layer of the substrate, and stops on a silicon nitride barrier, just above the underlying metal layer. Next, the via photoresist layer is stripped, and the trench photoresist is applied and lithographically patterned. Typically, some of the photoresist will remain in the bottom of the via, or the via may be covered by an organic ARC plug, in order to prevent the lower portion via from being over-etched during the trench etch process. A second anisotropic etch then cuts through the surface cap material and etches the low-k material down to a desired depth. This etch forms the trench. The photoresist is then stripped and the Silicon Nitride barrier at the bottom of the via is opened with a very soft, low-energy etch that will not cause the underlying copper to sputter into the via. As described above, the trench and via are filled with a conductive material (e.g., aluminum (Al), Copper (Cu), etc.) and polished by chemical mechanical polishing (CMP).

An alternate methodology is trench-first. In one example, the substrate is coated with photoresist and a trench lithographic pattern is applied. An anisotropic dry etch then cuts through the surface hard mask (again typically SiN, TiN or TaN) followed by stripping the photoresist. Another photoresist is applied over the trench hard mask and then the vias are lithographically patterned. A second anisotropic etch then cuts through cap layer and partially etches down into the low-k material. This etch forms the partial vias. The photoresist is then stripped for trench etch over the vias with the hard mask. The trench etch then cuts through the cap layer and partially etches the low-k material down to desired depth. This etch also clears via holes at the same time stopping on the final barrier located at the bottom of the via. The bottom barrier is then opened with a special etch.

A third methodology is dual hard mask. This method combines the oxide etch steps but requires two separate ILD (interlevel dielectric) depositions with an intervening nitride mask and etch step. The lower (via) dielectric is deposited with a nitride etch stop on both top and bottom. The top nitride is masked and etched to form a via hard mask. This requires a special nitride etch process. Then the top (line) dielectric is deposited. Finally, the trench mask is aligned with the via openings that have been etched in the nitride, and both the trench and vias are etched in both layers of oxide with one etch step.

To facilitate discussion, FIG. 2A illustrates an idealized cross-sectional view of the layer stack, representing the layers of an exemplar substrate, prior to a lithographic step. In the discussions that follow, terms such as “above” and “below,” which may be employed herein to discuss the spatial relationship among the layers, may, but need not always, denote a direct contact between the layers involved. It should be noted that other additional layers above, below, or between the layers shown may be present. Further, not all of the shown layers need necessarily be present and some or all may be substituted by other different layers.

At the bottom of the layer stack, there is shown a layer 208, comprising a semi-conductor. Above layer 208 is disposed a barrier layer 204, typically comprising nitride or carbide (SiN or SiC). Dual damascene substrates further comprise a set of metal layers including M1 209a-b, typically comprising aluminum or copper. Above the barrier layer 204, is disposed a intermediate dielectric (IMD) layer 206, comprising a low-k material (e.g., SiOC, etc.). Above the IMD layer 206, there may be placed a cap layer 203, typically comprising SiO₂. Above cap layer 203, there may be disposed a trench mask layer 202, typically comprising TiN, SiN, or TaN.

FIG. 2B shows a somewhat idealized cross-sectional view of the layer stack of FIG. 2A, after photoresist layer 220 and a BARC layer 212 is further added.

FIG. 2C shows a somewhat idealized cross-sectional view of the layer stack of FIG. 2B after photoresist layer 220 and BARC layer 212 have been processed through lithography. In this example, a photoresist mask pattern is created with a set of trenches 214a-b.

FIG. 2D shows the cross-sectional view of the layer stack of FIG. 2C after trench mask layer 201 has been processed in the plasma system, further extending trench 214a-b to cap layer 203.

FIG. 2E shows the cross-sectional view of the layer stack of FIG. 2D, after photoresist layer 220 and a BARC layer 212 are removed.

FIG. 2F shows the cross-sectional view of the layer stack of FIG. 2E after a second photoresist layer 216 and a BARC layer 218 are disposed, in order to create a second metal layer and a via connecting it to the first metal layer 209a-b.

FIG. 2G shows the cross-sectional view of the layer stack of FIG. 2F after the photoresist layer has been opened and an etch has been performed to partially etch into IMD layer 206 to create a via.

FIG. 2H shows the cross-sectional view of the layer stack of FIG. 2G after photoresist layer 216 and BARC layer 218 have been stripped, and an additional etch process has been performed to extend the trench to a desired depth and etch through a via stopping on barrier layer 204.

In FIG. 21, the barrier layer 204 is etched through using, for example CH₂F₂, CH₃F, etc.

In FIG. 2J, a chemical mechanical polish process has been performed to polish the layer stack down to cap layer 203, and a conductive material (e.g., aluminum (Al), Copper (Cu), etc.) has been deposited to contact the existing M1 metal material.

Among the most important process steps during a plasma etch process is endpoint. Endpoint generally refers to a set of values, or a range, in a plasma process (e.g., time) for which a process is considered complete. For example, when etching a via, it is important to determine when a barrier layer, such as SiN, has been substantially penetrated, in order minimize the amount of etching into the underlying layer.

However, with these and other plasma processes, it is often difficult to monitor the process since process conditions may be dynamic within a plasma processing system because of chamber residue build up, plasma damage to chamber structures, etc.

One common technique used in plasma processing systems is optical emission spectroscopy (OES). In OES, an optical emission from a set of selected chemical species (i.e., such as radicals, ions, etc.) in a plasma processing system may be correlated to a process threshold, such as endpoint. That is, each type of activated species within the plasma processing chamber generally possesses a unique spectral signature, usually corresponding to a unique set of electromagnetic radiation wavelengths (usually between about 245 nm to about 800 nm). By monitoring for the intensity of a specific wavelength not substantially produced by any other species or by the plasma process itself, a process threshold can be determined by observing a change in the relative amount of a specific species in the plasma chamber.

For example, when SiO₂ is etched using a CF-based etchant (e.g., CF₄), a CO species is generally produced with a specific wavelength of about 483.5 nm. Likewise, when SiN is also etched CF-based etchant, an N species is generally produced with a specific wavelength of about 674 nm. Once the appropriate SiO₂ or SiN material is substantially consumed, the corresponding wavelength of the produced species generally drops, signaling that the process has achieved endpoint.

Referring now to FIG. 3, a simplified example of an optical emission spectrum snapshot for a blanket oxide substrate (Ar/C₄F₈/CH₂F₂/O₂ Chemistry −6 kW/50 mTorr) in which wavelength (304) is mapped to signal intensity (302). In this sample, CF₂ (306) shows prominent spectra emissions for 275 nm and 321 nm. CO (308) shows prominent spectra emissions for 451 nm, 520 nm, 561 nm, and 662 nm. H (310) shows prominent spectra emissions for 656 nm. While Ar (312) shows prominent spectra emissions for 750 nm.

However, a problem with current optical spectrometry endpoint detection methods may be that the plasma optical emissions are sensitive to changes in the chamber conditions. In some instances these changes in the plasma optical emissions can be comparable to an expected change used to trigger an endpoint call, thus causing a false endpoint call to occur. In addition, since only a small fraction of the total surface area (generally less than about 1%) may actually produce a signal change at endpoint, the change may be difficult to detect in the presence of the background chamber OES signal. Furthermore, effective mission spectral analysis is also made more difficult by the escalating requirements for substrates with sub-micron via contacts and high aspect ratios.

In view of the foregoing, there are desired methods and apparatus for determining endpoint in a plasma processing system.

### SUMMARY OF THE INVENTION

The invention relates, in one embodiment, in a plasma processing system, to a method of determining a process threshold is disclosed. The method includes exposing a substrate to a plasma process, including a process start portion, a substantially steady state portion, and process end portion. The method also includes collecting a first set of data during the substantially steady state portion; creating a first statistical model comprising at least a statistical model component selected from the group consisting of a variance component and a residual component; and collecting a second set of data. The method further includes creating a second statistical model comprising the statistical model component, wherein if the statistical model component of the first statistical model is substantially different than the statistical model component of the second statistical model, the process threshold has been substantially achieved.

The invention relates, in one embodiment, in a plasma processing system, to an apparatus for determining a process threshold. The method includes a means for exposing a substrate to a plasma process, including a process start portion, a substantially steady state portion, and process end portion. The method also includes a means for collecting a first set of data during said substantially steady state portion; a means for creating a first statistical model comprising at least a statistical model component selected from the group consisting of a variance component and a residual component; and a means for collecting a second set of data. The method further includes a means for creating a second statistical model comprising said statistical model component, wherein if said statistical model component of said first statistical model is substantially different than said statistical model component of said second statistical model, said process threshold has been substantially achieved.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a simplified diagram of a plasma processing system;

FIGS. 2A-2J show an idealized cross-sectional view of the layer stack, representing the layers of an exemplar substrate;

FIG. 3 shows a simplified example of an optical emission spectrum snapshot for a blanket oxide substrate;

FIG. 4 shows a simplified process is shown for employing a statistical model is used in a plasma processing system in which variance is used to determine a process threshold (i.e., endpoint, etc.), according to one embodiment of the invention;

FIG. 5 shows a simplified process is shown for employing a statistical model is used in a plasma processing system in which residual is used to determine a process threshold, according to one embodiment of the invention;

FIG. 6 shows a simplified diagram showing the optical emission of CF₂ for a substrate in a plasma processing system, according to one embodiment of the current invention.

FIG. 7 shows a simplified diagram in which a set of Hotelling T variances are generated from a set of statistical models that comprise a set of substantially steady state measurements and a set of process end measurements, according to one embodiment of the invention; and

FIG. 8 shows a simplified diagram in which a set of q statistic residuals are generated from a set of statistical models that comprise a set of substantially steady state measurements and a set of process end measurements, according to one embodiment of the invention.

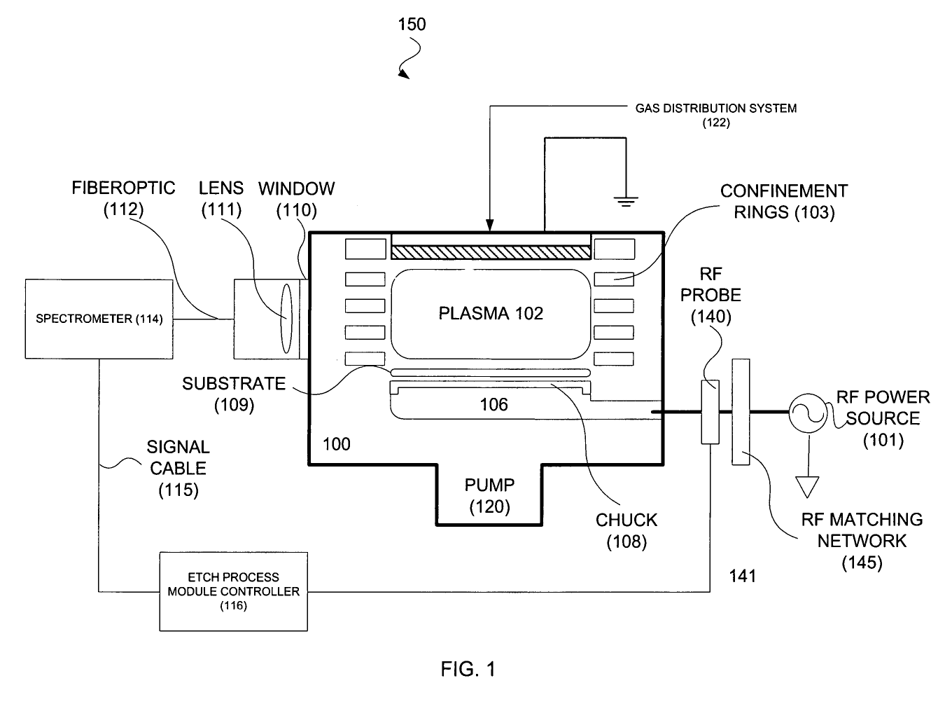

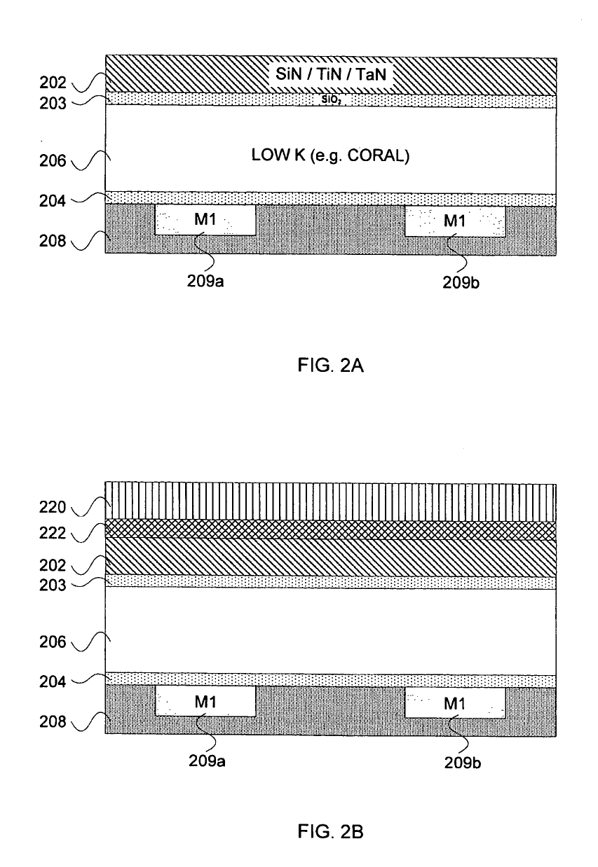

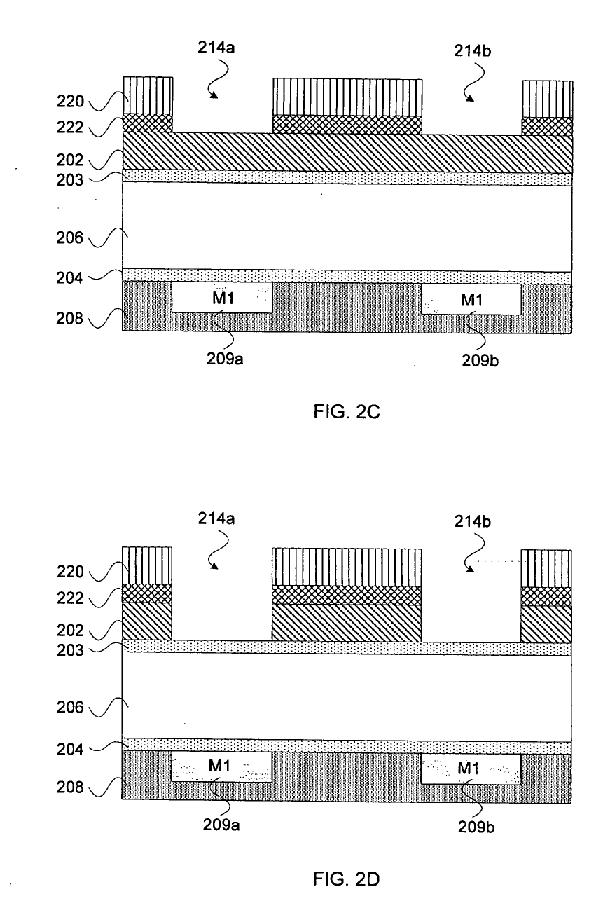

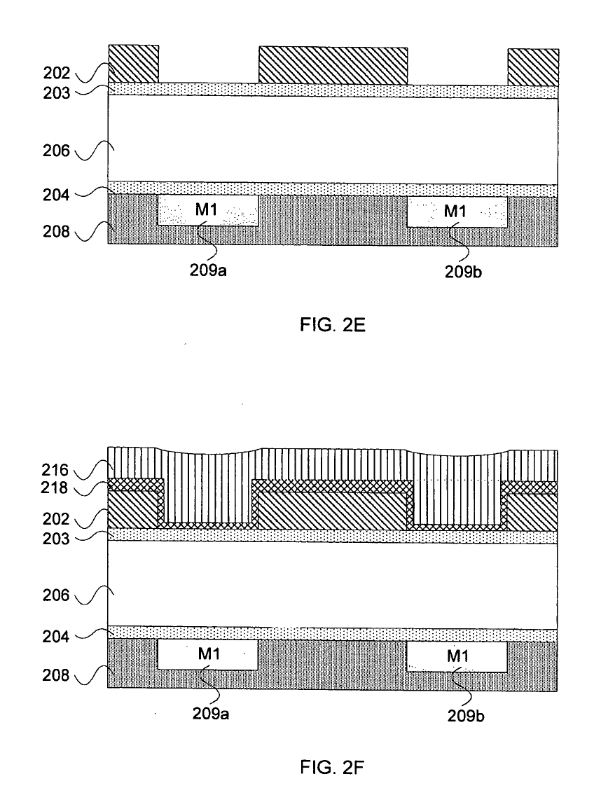

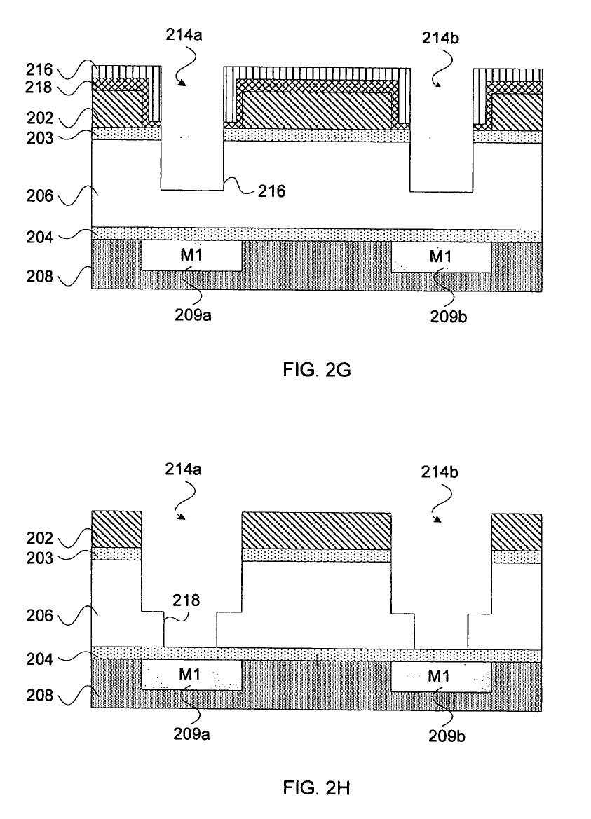

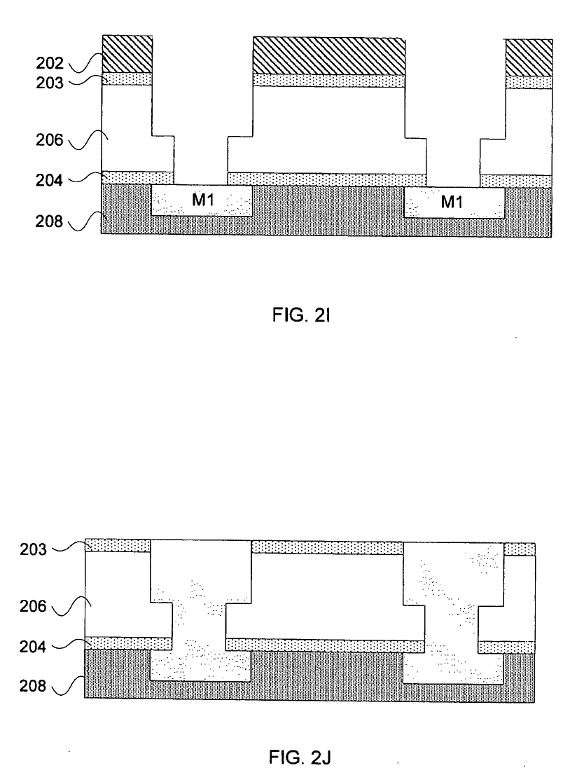

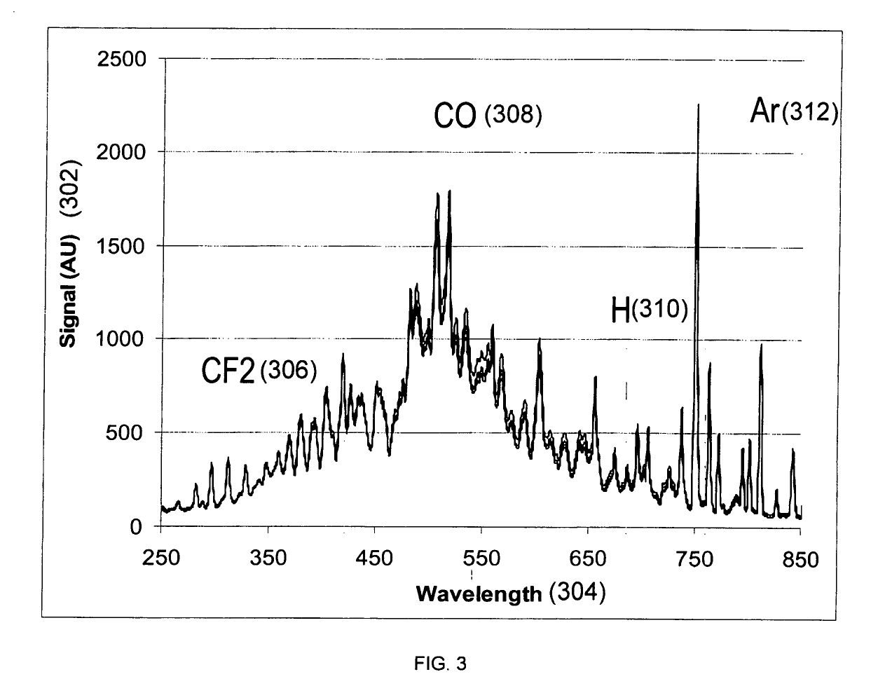

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

While not wishing to be bound by theory, it is believed by the inventor herein that a statistical model of the plasma process can be used to determine a process threshold, such as etch endpoint. Generally, many statistical analysis techniques are able to transform a set of measurements or samples into a statistical model that reasonably describes and possibly predicts the observed measurements.

The statistical model itself may be comprised of first set of elements that describe how a new sample conforms to the statistical model (often called variance) and a second set of elements that captures the variation in a new sample that does not conform to the statistical model (often called residual). In a non-obvious fashion, a relatively more sensitive statistical model may be created from a set of measurement during a portion of the plasma process with relatively small variation. That is, the variance and residual of the statistical model may be relatively small. A new subsequent measurement that substantially increases the variance or residual may signal a process threshold, such as etch endpoint. In one embodiment, the statistical model is created for each individual substrate, subsequently decreasing the sensitivity of process threshold detection caused by process matching, plasma chamber matching, and substrate matching. In another embodiment, the statistical model includes a set of confinement rings. In another embodiment, the statistical model includes a low open area etching plasma process.

As previously stated, with these and other plasma processes, however, it is often difficult to monitor the process since process conditions may be dynamic within a plasma processing system because of chamber residue build up, plasma damage to chamber structures, etc.

A common statistical technique used in dynamic environments is principal components analysis (PCA). A multivariate technique, PCA can correlate a number of variables that are periodically measured and subsequently transformed to a smaller set of uncorrelated variables, or factors, that describe the major variations in a data set. PCA finds combinations of variables or factors that describe major trends in the data set and expresses each as a series of principal components. For example, PCA may be used to create factorized model based on a set of sequentially measured electromagnetic emission spectra during a target etch step.

Once the PCA model is created, subsequent measurements can then be compared to the PCA model to determine a process threshold, such as endpoint. Endpoint generally refers to a set of values, or a range, in a plasma process (e.g., time) for which a process is considered complete. Generally, a process engineer defines the range of measurements that are required before a substantially representative PCA model can be created based on the information from the plasma process (e.g., etch rate, etc.).

In order to increase the sensitivity of the statistical model, the model may be created from a substantially steady state period of the process. That is, most plasma processes are commonly comprised of three phases: process start, steady state, and process end. During the process start phase, where pressure, power, and chemistry may exhibit significant transients prior to the plasma stabilizing, the corresponding set of measurements will typically have a relatively high variance (for PCA commonly measured by the T² statistic) and residual (for PCA commonly measured by the Q statistic). After a certain interval of time, commonly a few seconds, the process enters a steady state period in which subsequent measurements tend to have a relatively low variance and residual. Finally, during the process end phase, the corresponding set of measurements again tends to have relatively high variance and residual.

By creating the initial statistical model from a steady state set of measurements, the overall model variation and residual component is relatively small when compared to a model that includes both the process start and the steady state phase. Although crossing from the steady state phase into the process end phase may have minimum variation in OES signal, a PCA projection which is using PCA model may still capture a sufficient increase in variance and residual to determine that a process threshold has been achieved. Once the PCA model from steady state is determined with substantially specific numbers of principle components, the PCA projection may calculate PCA parameters (e.g., Q, T2, etc.) in the end phase using eigenvalues and eigenvectors of covariance acquired from the steady state phase.

In U.S. Pat. No. 5,288,367, there has been proposed a method where a specific wavelength of an emission spectrum is automatically determined using an approach of a principal component analysis and an end point of etching is detected on the basis of the specific wavelength. According to this method, a specific wavelength can automatically be determined. However, unlike the present invention, this method comprises a statistical model that includes both the process start, the steady state phase and end phase. That is, the intensity for each measured spectra is continually tracked and PCA modeled from the beginning to the end of the process, as opposed to the substantially PCA modeling for steady state portion of the process and PCA projection onto end phase, as the present invention. In addition, U.S. Pat. No. 5,288,367 relies principally on a set of principal components to determine endpoint, as opposed to using the variance or residual of a statistical model, as the current invention.

Mathematically, PCA relies on an eigenvector decomposition of the covariance or correlation matrix of the process variables. For a given data matrix X with m rows and n columns the covariance matrix of X is defined as:

$$cov ( X ) = \frac{{X}^{T} X}{m - 1} \qquad ( Equation 1 )$$

Once the columns of X have been mean centered (i.e. adjusted to have a zero mean by subtracting off the mean of each column) autoscaled (i.e., adjusted to zero mean and unit variance by dividing each column by its standard deviation) equation 1 gives the correlation matrix of X.

PCA decomposes the data matrix X as the sum of the outer product of vectors tᵢ and pᵢ plus a residual matrix E:
X=tᵢp^{T}₁+t₂p^{T}₂+. . . +tₖp^{T}ₖ+E (Equation 2)
The tᵢ vectors are known as scores and contain information on how the samples relate to each other, where as pᵢ vectors are eigenvectors of the covariance.

The first principal component (tᵢp^{T}₁) is typically not used to determine endpoint, generally accounts for about 80% of the total variance and tracks the average signal level changes due to drifting window transmission caused by deposition of the window, etc. The second (t₂p^{T}₂),third (t₃p^{T}₃), and possibly fourth principal components generally account for less than 20% of the total variance, and may generally be used to detect endpoint. The remaining principal components generally contain noise, and hence generally are not used for meaningful patterns.

It is also possible to calculate a residual, Q statistic, for each sample. Q is simply the sum of squares of each row of E (from Equation 2), for example, for the ith sample in X, xi:
Qi=eᵢeᵢ^{T}=xⁱ(I−PₖPₖ^{T})xᵢ^{T} (Equation 3)
where eᵢ is the ith row of E, Pₖ is the matrix of the first k loadings vectors retained in the PCA model (where each vector is a column of Pk) and I is the identity matrix of appropriate size (n by n). Therefore, if the PCA model is generated by mₜₕ number of principal components from steady state, Qj in end phase by PCA projection is expressed as:
Qj=eⱼeⱼ^{T}=x^{j}(I−PₘPₘ^{T})xⱼ^{T} (Equation 4)
The Q statistic is a measure of the amount of variation in each sample not captured by the m principal components retained in the model from steady state. At the same time, it is a measure of the amount of new variation in end phase opposed to steady state. As previously stated, by creating the PCA model from measurements in steady state period and executing PCA projection onto end phase, the Q statistic may signal crossing a process threshold, such as endpoint.

A measure of the variation within the PCA model is given by Hotelling's T² statistic. T² is the sum of normalized squared scores defined as:
Tᵢ²=tᵢλ⁻¹tᵢ^{T}=xᵢPₖλ⁻¹Pₖ^{T}xᵢ^{T}(Equation 5)
where ti in this instance refers to the ith row of Tk, the matrix of k scores vectors from the PCA model. The matrix l−1 is a diagonal matrix containing the inverse eigenvalues associated with the k eigenvectors (principal components) retained in the model. If the PCA model is generated by mₜₕ number of principal components from steady state, Tj² in end phase by PCA projection is expressed as:
Tⱼ²=tⱼλ⁻¹tⱼ^{T}=xⱼPₘλ⁻¹Pₘ^{T}xⱼ^{T} (Equation 6)
Where Pₘ is the matrix of loading vector of PCA model from steady state. As previously stated, by creating the PCA model from measurements in steady state period, the T² statistic by PCA projection in end phase may signal crossing a process threshold, such as endpoint.

Common plasma processing system measurements that may be used with PCA are: plasma species presence or concentration as measured with optical emission, residual gas analyzers, optical absorption, etc, bias voltage of the substrate electrode, ESC DC currents, and other electrical parameters such as RF voltage, current, phase, and associated harmonics, RF tuning frequency for matching the plasma to generator impedance in frequency tuned systems, or RF tuning capacitance/inductance for matching plasma to generator impedance in variable capacitor/inductor matching networks.

For example, in endpoint determination, various aspects of the plasma processes can be measured (e.g., optical emission signal strengths at wavelengths corresponding to specific species, electrical measurements, etc) and then transformed into a statistical model that can substantially determine endpoint.

As previously stated, endpoint determination is problematic for plasma processes that target etching relatively small open (unmasked) areas of the substrate's total surface area (e.g., low open area etching, etc.). This issue is further aggravated when using OES, since a small change in a given species can make the corresponding signal change difficult to detect in the presence of the background signal from this species, present in the plasma at some level prior to endpoint.. In particular, these perturbations in the plasma optical emissions can be comparable to an expected perturbation used to trigger an endpoint call, thus causing a false endpoint call to occur.

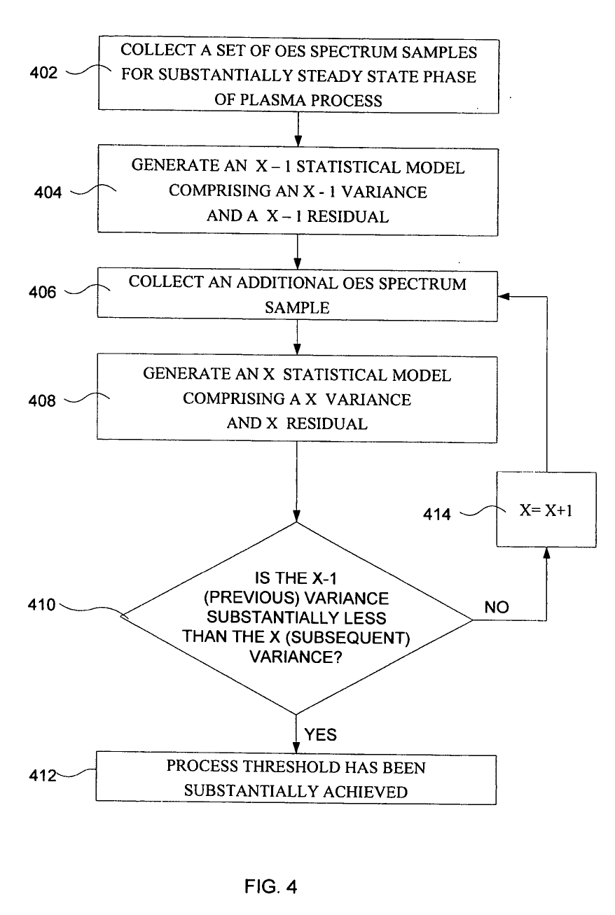

Referring now to FIG. 4, a simplified process is shown for employing a statistical model is used in a plasma processing system in which variance is used to determine a process threshold (i.e., endpoint, etc.), according to one embodiment of the invention. Initially, a set of OES spectrum samples are collected for substantially steady state phase of plasma process at 402. Next, an initial statistical model (e.g., PCA, etc.) is created. That is, a x−1 statistical model is generated comprising an x−1 variance and a x−1 residual, at 404. An additional OES spectrum sample is then collected, at 406. A second statistical model is then generated. That is, an x statistical model comprising a x variance and x residual is generated at 408. If the x−1 (previous) variance is not substantially less than the x (subsequent) variance, at 410, then process threshold has not been reached, and the monitoring process continues with x=x+1, at 414. That is, an additional OES spectrum sample is again collected, at 406, and another statistical model is generated. If the x−1 (previous) variance is substantially less than the x (subsequent) variance, at 410, then the process threshold has been reached, at 412.

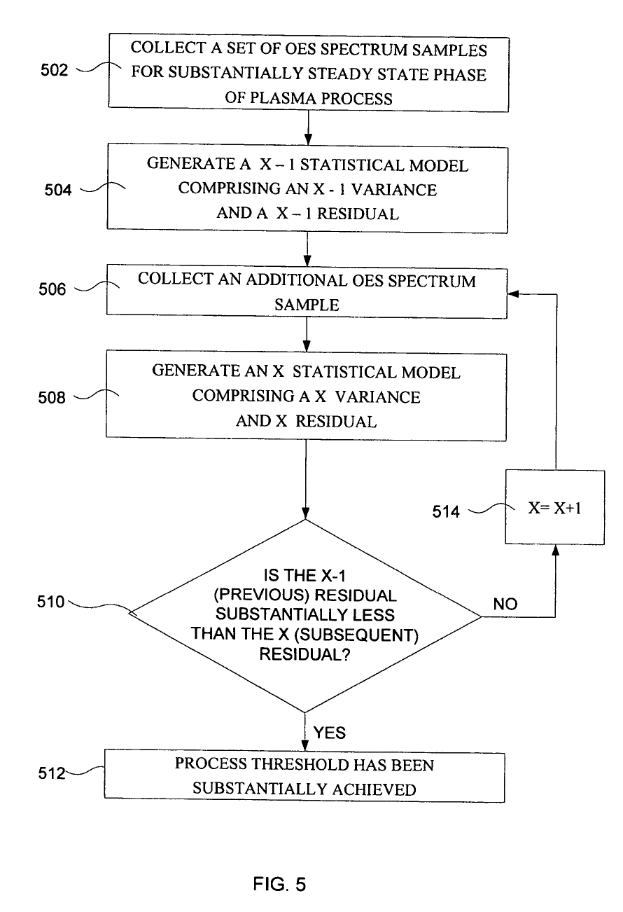

Referring now to FIG. 5, a simplified process is shown for employing a statistical model is used in a plasma processing system in which residual is used to determine a process threshold (i.e., endpoint, etc.), according to one embodiment of the invention. Initially, a set of OES spectrum samples are collected for substantially steady state phase of plasma process at 502. Next, an initial statistical model (e.g., PCA, etc.) is created. That is, an x−1 statistical model is generated comprising an x−1 variance and a x−1 residual, at 504. An additional OES spectrum sample is then collected, at 506. A second statistical model is then generated. That is, an x statistical model comprising a x variance and x residual is generated at 508. If the x−1 (previous) residual is not substantially less than the x (subsequent) residual, at 510, then process threshold has not been reached, and the monitoring process continues with x=x+1, at 514. That is, an additional OES spectrum sample is again collected, at 506, and another statistical model is generated. If the x−1 (previous) residual is substantially less than the x (subsequent) residual, at 510, then the process threshold has been reached, at 512.

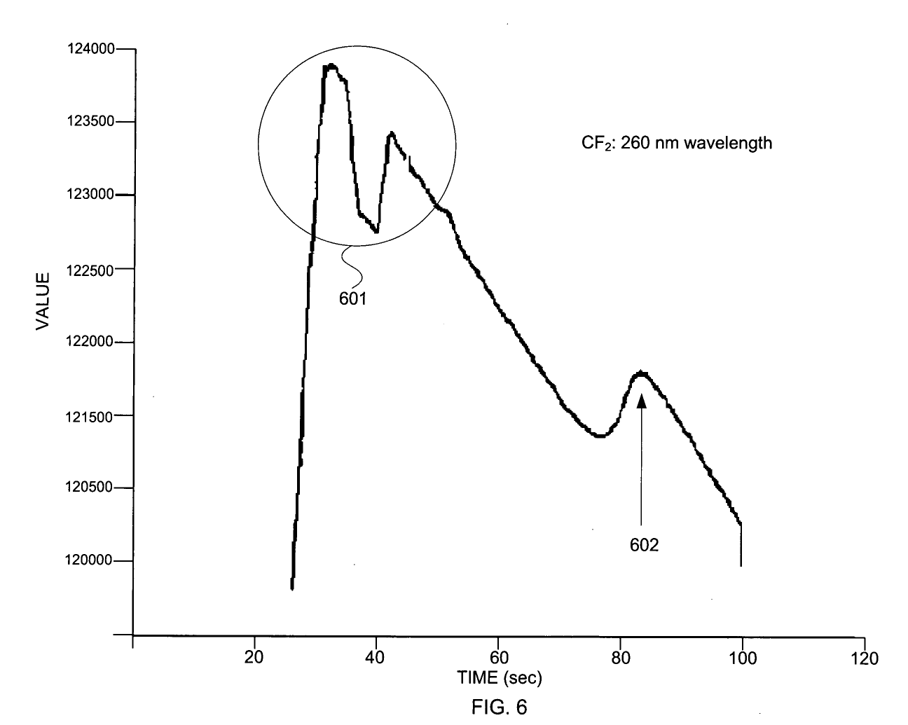

Referring now to FIG. 6, a simplified diagram showing the optical emission of CF₂ for a substrate in a plasma processing system (50 mT/6 kW/Ar/C₄F₈/O₂ process) in which only about 0.8% of the substrate's surface area is unmasked and etched, according to one embodiment of the current invention. After about 70 seconds, at 402, process endpoint occurs. However, since the etched surface area is less than about 1% of the substrate's total surface area, the corresponding detectable signal change at a wavelength 260 nm is only about 0.5%.

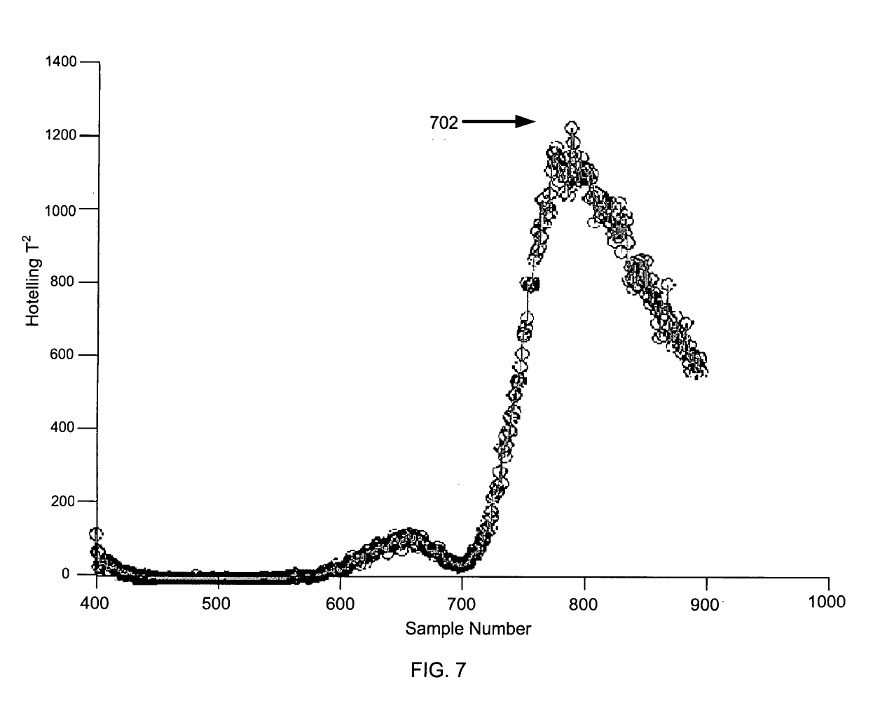

Referring now to FIG. 7, a simplified diagram in which a set of Hotelling T² variances are generated from a set of statistical models that comprise a set of substantially steady state measurements and a set of process end measurements, according to one embodiment of the invention. As previously described, the initial set of statistical models is created from a set of steady state measurements. Hence, the overall model variance and residual are relatively small when compared to a model that includes both the process start and the steady state phase. Crossing the from the steady state phase into the process end phase at about 80 seconds, at 702, may substantially increase the variance and residual of the statistical model, signaling that a plasma process threshold has been achieved, such as endpoint.

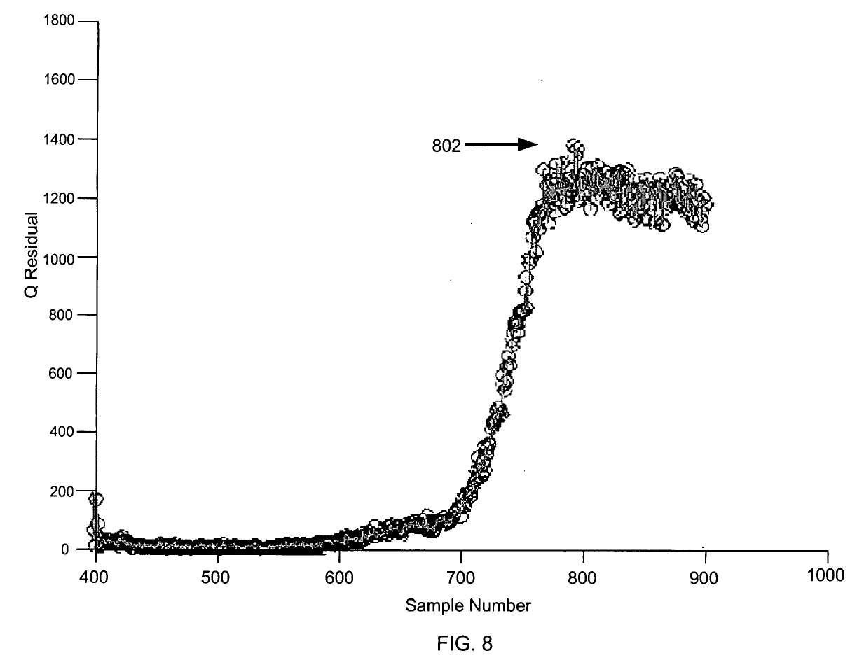

Referring now to FIG. 8, a simplified diagram in which a set of q statistic residuals are generated from a set of statistical models that comprise a set of substantially steady state measurements and a set of process end measurements, according to one embodiment of the invention. As previously described, the initial set of statistical models is created from a set of steady state measurements. Hence, the overall model variance and residual component are relatively small when compared to a model that includes both the process start and the steady state phase. Crossing the from the steady state phase into the process end phase at about 80 seconds, at 702, may substantially increase the variance and residual component of the statistical model, signaling that a plasma process threshold has been achieved, such as endpoint.

While this invention has been described in terms of several preferred embodiments, there are alterations, permutations, and equivalents which fall within the scope of this invention. For example, although the present invention has been described in connection with plasma processing systems from Lam Research Corp. (e.g., Exelan™, Exelan™HP, Exelan™ HPT, 2300™, Versys™ Star, etc.), other plasma processing systems may be used. This invention may also be used with substrates of various diameters (e.g., 200 mm, 300 mm, etc.). Also, photoresist plasma etchants comprising gases other than oxygen may be used. It should also be noted that there are many alternative ways of implementing the methods of the present invention.

In addition, other statistical analysis techniques may be used, such as partial least squares (PLS). Furthermore, the set of measurements may comprise electromagnetic radiation, physical changes in the plasma processing system (e.g., pressure, temperature, confinement ring position, etc.), and RF changes (RF bottom power, RFB reflected power, RF tuning frequency, RF load, phase error, RF power, RF impedance, RF voltage, RF current, etc.). The claimed invention may also be used to optimize a process model for other types of plasma processes in a plasma processing system.

Advantages of the invention include methods and apparatus for optimizing the determination of a process endpoint in a plasma processing system. Additional advantages include optimizing a process model in a plasma processing system; creating a more sensitive statistical model for process threshold determination, and the dynamic generation of a statistical model for each individual substrate. In above examples as shown in FIG. 6, the steady state portion was chosen during about 40<t<50 seconds. Note that signal perturbation occurs at about t=30−40 seconds 601 due to confinement ring motion. Such perturbations should be included in the first model set, if they are expected during the steady state portion. For example, those perturbations may occur if the confinement ring is not fixed.

Having disclosed exemplary embodiments and the best mode, modifications and variations may be made to the disclosed embodiments while remaining within the subject and spirit of the invention as defined by the following claims.

What is claimed is:

1. In a plasma processing system, a method of determining a process threshold comprising:
exposing a substrate to a plasma process, including a process start portion, a substantially steady state portion, and process end portion;
collecting a first set of data during said substantially steady state portion;
creating a first statistical model comprising at least a statistical model component selected from the group consisting of a variance component and a residual component; and
collecting a second set of data;
creating a second statistical model comprising said statistical model component, wherein if said statistical model component of said first statistical model is substantially different than said statistical model component of said second statistical model, said process threshold has been substantially achieved.

2. The method of claim 1, wherein said first statistical model and said second statistical model comprise principal component analysis.

3. The method of claim 1, wherein said first statistical model and said second statistical model comprise partial least squares.

4. The method of claim 1, wherein said plasma process is a etch process utilizing an etchant.

5. The method of claim 1, wherein said process threshold is endpoint.

6. The method of claim 4, wherein etchant is CF₄.

7. The method of claim 4, wherein etchant is CHF₃.

8. The method of claim 4, wherein etchant is C₄F₆.

9. The method of claim 4, wherein etchant is C₄F₈.

10. The method of claim 1, wherein said plasma process is low open area etching.

11. The method of claim 1, wherein said first set of data and said second set of data includes optical emission.

12. The method of claim 1, wherein said first set of data includes optical emission signal collected at multiple confinement ring position to include normal signal perturbation caused by the optical collection aperture change.

13. The method of claim 1, wherein said first set of data and said second set of data includes electrical measurements within the RF delivery system.

14. The method of claim 1, wherein said first set of data and said second set of data includes plasma species presence.

15. The method of claim 1, wherein said first set of data and said second set of data includes RF power.

16. The method of claim 1, wherein said plasma process is dielectric film etching.

17. The method of claim 1, wherein said first set of data and said second set of data includes chamber pressure.

18. The method of claim 1, wherein said first set of data and said second set of data includes a RF matching network tunable impedance.

19. The method of claim 1, wherein said first set of data and said second set of data includes a RF voltage measured on the RF delivery system.

20. The method of claim 1, wherein said first set of data and said second set of data includes wafer DC bias voltage.

21. The method of claim 1, wherein said first set of data and said second set of data includes impedance measured on the RF delivery system.

22. The method of claim 1, wherein said first set of data and said second set of data includes RF tuning frequency.

23. The method of claim 1, wherein said first statistical model and said second statistical model includes confinement ring movement.

24. In a plasma processing system, a method of build an in-situ substrate processing model comprising:
exposing a substrate to a plasma process, including a process start portion, a substantially steady state portion, and process end portion;
collecting a first set of data during said substantially steady state portion;
creating a first statistical model comprising at least a statistical model component selected from the group consisting of a variance component and a residual component;
collecting a second set of data;
creating a second statistical model comprising said statistical model component, wherein if said statistical model component of said first statistical model is substantially different than said statistical model component of said second statistical model, said process threshold has been substantially achieved.

25. In a plasma processing system, an apparatus for determining a process threshold comprising:
means for exposing a substrate to a plasma process, including a process start portion, a substantially steady state portion, and process end portion;
means for collecting a first set of data during said substantially steady state portion;
means for creating a first statistical model comprising at least a statistical model component selected from the group consisting of a variance component and a residual component;
means for collecting a second set of data; and
means for creating a second statistical model comprising said statistical model component, wherein if said statistical model component of said first statistical model is substantially different than said statistical model component of said second statistical model, said process threshold has been substantially achieved.

26. The apparatus of claim 25, wherein said first statistical model and said second statistical model comprise principal component analysis.

27. The apparatus of claim 25, wherein said first statistical model and said second statistical model comprise partial least squares.

28. The apparatus of claim 25, wherein said plasma process is a etch process utilizing an etchant.

29. The apparatus of claim 25, wherein said process threshold is endpoint.

30. The apparatus of claim 4, wherein etchant is CF₄.

31. The apparatus of claim 4, wherein etchant is CHF₃.

32. The apparatus of claim 4, wherein etchant is C₄F₆.

33. The apparatus of claim 4, wherein etchant is C₄F₈.

34. The apparatus of claim 25, wherein said plasma process is low open area etching.

35. The apparatus of claim 25, wherein said first set of data and said second set of data includes optical emission.

36. The apparatus of claim 25, wherein said first set of data includes optical emission signal collected at multiple confinement ring position to include normal signal perturbation caused by the optical collection aperture change.

37. The apparatus of claim 25, wherein said first set of data and said second set of data includes electrical measurements within the RF delivery system.

38. The apparatus of claim 25, wherein said first set of data and said second set of data includes plasma species presence.

39. The apparatus of claim 25, wherein said first set of data and said second set of data includes RF power.

40. The apparatus of claim 25, wherein said plasma process is dielectric film etching.

41. The apparatus of claim 25, wherein said first set of data and said second set of data includes chamber pressure.

42. The apparatus of claim 25, wherein said first set of data and said second set of data includes RF matching network tunable impedance.

43. The apparatus of claim 25, wherein said first set of data and said second set of data includes RF voltage measured on the RF delivery system.

44. The apparatus of claim 25, wherein said first set of data and said second set of data includes wafer DC bias voltage.

45. The apparatus of claim 25, wherein said first set of data and said second set of data includes impedance measured on the RF delivery system.

46. The apparatus of claim 25, wherein said first set of data and said second set of data includes RF tuning frequency.

47. The apparatus of claim 25, wherein said first statistical model and said second statistical model includes confinement ring movement.

48. In a plasma processing system, an apparatus of build an in-situ substrate processing model comprising:
means for exposing a substrate to a plasma process, including a process start portion, a substantially steady state portion, and process end portion;
means for collecting a first set of data during said substantially steady state portion;
means for creating a first statistical model comprising at least a statistical model component selected from the group consisting of a variance component and a residual component;
means for collecting a second set of data; and
means for creating a second statistical model comprising said statistical model component, wherein if said statistical model component of said first statistical model is substantially different than said statistical model component of said second statistical model, said process threshold has been substantially achieved.
